(19) United States
(12) Patent Application Publication
(10) Pub. No.: US 2014/0124926 A1
(43) Pub. Date: May 8, 2014

(54) Method And System For A Chaser Pellet In A Semiconductor Package Mold Process

(71) Applicant: Corey Reichman, Mesa, AZ (US)

(72) Inventor: Corey Reichman, Mesa, AZ (US)

(21) Appl. No.: 13/671,194

(22) Filed: Nov. 7, 2012

(51) Int. Cl. H01L 21/56; H01L 23/28

(52) U.S. Cl. CPC H01L 21/563; H01L 23/28
USPC 257/738; 438/127

(57) ABSTRACT

Methods and systems for a chaser pellet in a semiconductor mold process are disclosed and may include a semiconductor package comprising semiconductor die coupled to a packaging substrate where the packaging substrate and the coupled semiconductor die may be placed in a mold chase. A chaser pellet may be placed on a target pellet comprising low alpha epoxy mold compound (EMC) in a pellet chamber coupled to the mold chase via a runner. Heat may be applied to the pellet chamber to melt the target pellet. Pressure may be applied to the chaser pellet to force EPM from the molten target pellet through the runner to the mold chase. The die may be encapsulated with the epoxy mold compound from the molten target pellet. Passive devices may be coupled to the semiconductor package and may be encapsulated by the EPM from the molten target pellet.

### CROSS-REFERENCE TO RELATED APPLICATIONS/INCORPORATION BY REFERENCE

[Not Applicable]

### FIELD OF THE INVENTION

Certain embodiments of the invention relate to semiconductor chip packaging. More specifically, certain embodiments of the invention relate to a method and system for a chaser pellet in a semiconductor package mold process.

### BACKGROUND OF THE INVENTION

Semiconductor packaging protects integrated circuits, or chips, from physical damage and external stresses. In addition, it can provide a thermal conductance path to efficiently remove heat generated in a chip, and also provide electrical connections to other components such as printed circuit boards, for example. Materials used for semiconductor packaging typically comprise ceramic or plastic, and form-factors have progressed from ceramic flat packs and dual in-line packages to pin grid arrays and leadless chip carrier packages, among others.

Further limitations and disadvantages of conventional and traditional approaches will become apparent to one of skill in the art, through comparison of such systems with the present invention as set forth in the remainder of the present application with reference to the drawings.

### BRIEF DESCRIPTION OF SEVERAL VIEWS OF THE DRAWINGS

FIG. 1 is a drawing illustrating an integrated circuit package with a mold cap formed utilizing a chaser pellet, in accordance with an example embodiment of the invention.

FIG. 2 is a diagram illustrating an apparatus for applying mold material to a semiconductor die and packaging substrate, in accordance with an example embodiment of the invention.

FIG. 3 is a drawing illustrating utilization of a chaser pellet to apply mold material to a semiconductor die and packaging substrate, in accordance with an example embodiment of the invention.

FIG. 4 is a flow diagram illustrating a mold encapsulation process utilizing a chaser pellet, in accordance with an example embodiment of the invention.

### DETAILED DESCRIPTION OF THE INVENTION

Certain aspects of the invention may be found in a method and system for a chaser pellet in a semiconductor package mold process. Example aspects of the invention may comprise a semiconductor package comprising one or more semiconductor die coupled to a packaging substrate where the packaging substrate and the one or more coupled semiconductor die may be placed in a mold chase. A chaser pellet may be placed on top of a target pellet in a pellet chamber coupled to the mold chase via a runner, wherein the target pellet comprises an epoxy mold compound. Heat may be applied to the pellet chamber to melt the target pellet. Pressure may be applied to the chaser pellet to force epoxy mold compound from the molten target pellet through the runner to the mold chase. The one or more semiconductor die may be encapsulated with the epoxy mold compound from the molten target pellet. One or more passive devices may be coupled to the packaging substrate and may be encapsulated by the epoxy mold compound from the molten target pellet. The target pellet may comprise a low alpha material. The low alpha material may, for example, emit less than 0.002 alpha particle counts per hour per square centimeter. Alternatively, for example, the low alpha material may, for example, emit less than 0.001 alpha particle counts per hour per square centimeter. The epoxy mold compound may comprise an underfill material for the one or more semiconductor die. A vacuum may be applied at the mold chase to force the epoxy mold compound from the molten target pellet through the runner to the mold chase. The semiconductor package may comprise a flip chip molded ball grid array.

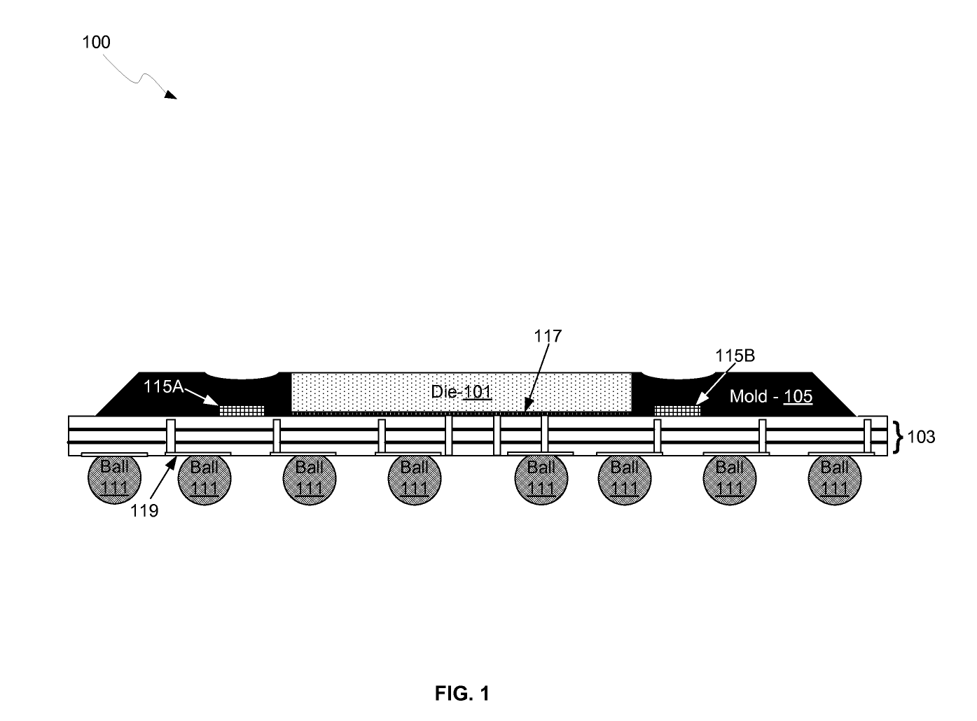

FIG. 1 is a drawing illustrating an integrated circuit package with a mold cap formed utilizing a chaser pellet, in accordance with an example embodiment of the invention. Referring to FIG. 1, there is shown a package 100 comprising a die 101, a packaging substrate 103, solder balls 111, and passive devices 115A and 115B.

The die 101 may, for example, comprise an integrated circuit die that has been separated from a semiconductor wafer. The die 101 may comprise electrical circuitry such as digital signal processors (DSPs), network processors, power management units, audio processors, RF circuitry, wireless baseband system-on-chip (SoC) processors, sensors, and application specific integrated circuits, for example. In addition, the die 101 may comprise micro-bumps 117 for providing electrical contact between the circuitry in the die 101 and contact pads on the surface of the packaging substrate 103.

The packaging substrate 103 may comprise a mechanical support structure for the die 101 and the passive devices 115A and 115B. The packaging substrate 103 may comprise solder balls 111 on the bottom surface for providing electrical contact to external devices and circuits, for example. Though the example package 100 includes solder balls 111, any of a variety of alternative conductive attachment features may be utilized in place of or in addition to the illustrated solder balls 111. The packaging substrate 103 may also comprise conductive traces in a non-conductive material for providing conductive paths from the solder balls 111 to the die 101 via pads that are configured to receive the micro-bumps 117 of the die 101. Additionally, the packaging substrate 103 may comprise pads 119 for receiving the solder balls 111. The pads 119 may comprise one or more under-bump metals, for example, for providing a proper electrical and mechanical contact between the packaging substrate 103 and the solder balls 111.

The passive devices 115A and 115B may comprise electrical devices such as resistors, capacitors, and inductors, for example, which may provide functionality to devices and circuits in the die 101. The passive devices 115A and 115B may comprise devices that may be difficult to integrate in the integrated circuits in the die 101, such as high value capacitors or inductors. In another example scenario, the passive devices 115A and 115B may comprise one or more crystal oscillators for providing one or more clock signals to the die 101.

Mold material 105, from which a mold cap of the package 100 is formed, may comprise an epoxy mold compound, for example. The mold material 105 may be utilized to encapsulate (e.g., completely or partially) the die 101 and the passive devices 115A and 115B on the packaging substrate 103. In addition, the mold material 105 may be utilized as an underfill material, filling the volume between the die 101 and the packaging substrate 103. In another example scenario, underfill material may be placed under the die 101 prior to placing the mold material 105, such as through a capillary underfill or pre-applied underfill process. As shown in FIG. 1, the mold material 105 forms a mold cap that surrounds the die 101 on all four sides and may also contact the lower side of the die 101 as an underfill. The top surface of the die 101 is left free of mold material, for example for subsequent addition of a heat sink. Note, however, that in various example embodiments, the top surface of the die 101 may also be covered with mold material.

In an example scenario, the mold material 105 may be placed about the die 101 and the packaging substrate 103 utilizing a mold material (e.g., epoxy) delivery system comprising a pellet chamber, a runner, and a gate. One or more pellets of mold material (e.g., epoxy mold material) may be placed in the pellet chamber and subjected to heating. The mold material 105 may, for example, comprise a low alpha material, meaning it emits alpha radiation below a threshold set for proper integrated circuit operation. In an example scenario, low alpha material may comprise material that emits less than 0.002 (or alternatively 0.001) alpha particle counts per hour per square centimeter.

Pressure may be applied to the one or more pellets and a vacuum may be generated at the gate end of the assembly to assist in the flow of the mold material out of the gate and onto the packaging substrate 103. Multiple die and packaging substrates may be molded concurrently with runners extending to each die/substrate assembly. However, material left in the runners after completing the encapsulation is wasted in the process. Therefore, in an example scenario, a chaser pellet may be utilized to push a target pellet of low alpha material through the runners and gates to encapsulate the one or more die and packaging substrates.

The chaser pellet may comprise a material that does not have the desired target pellet characteristics, i.e., it does not need to be low alpha material, which can be significantly more costly. In this manner, the more costly target pellet material may be used for encapsulation while the lower cost chaser pellet may be utilized to push the target material through and remain as waste in the runners, instead of the target pellet material.

While FIG. 1 illustrates a flip-chip molded ball grid array (FCmBGA), any packaging structure with mold material encapsulation may utilize the chaser pellet concept described herein. Similarly, the packaging structure is not limited to a single die. Accordingly, any number of semiconductor die may be bonded to the packaging substrate 103. Additionally, for example, a plurality of such packaging structures may be molded together (e.g., in a batch or gang molding process) followed by singulation into individual packages.

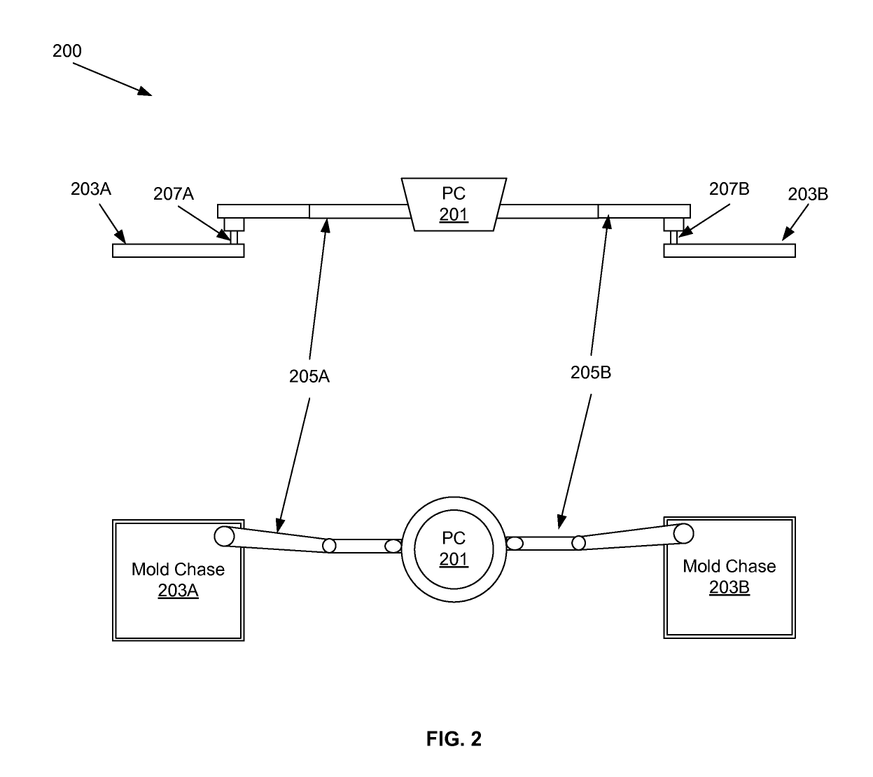

FIG. 2 is a diagram illustrating an apparatus for applying mold material to a semiconductor die and packaging substrate, in accordance with an example embodiment of the invention. Referring to FIG. 2, there is shown a mold apparatus 200 comprising a pellet chamber 201, mold chases 203A and 203B, runners 205A and 205B, and mold gates 207A and 207B. The top schematic is a side view of the mold apparatus 200, while the bottom drawing is a top view.

The pellet chamber 201 may comprise a container or crucible for inserting mold material pellets to be heated and transported to the mold chases 203A and 203B via the runners 205A and 205B. In an example scenario, the pellet chamber 201 may be heated utilizing radiative heating.

The runners 205A and 205B may comprise structures for channeling molten mold material from the pellet chamber 201 to the mold chases 203A and 203B, respectively. The runners 205A and 205B may be terminated by the mold gates 207A and 207B, which may direct the mold material into the mold chases 203A and 203B.

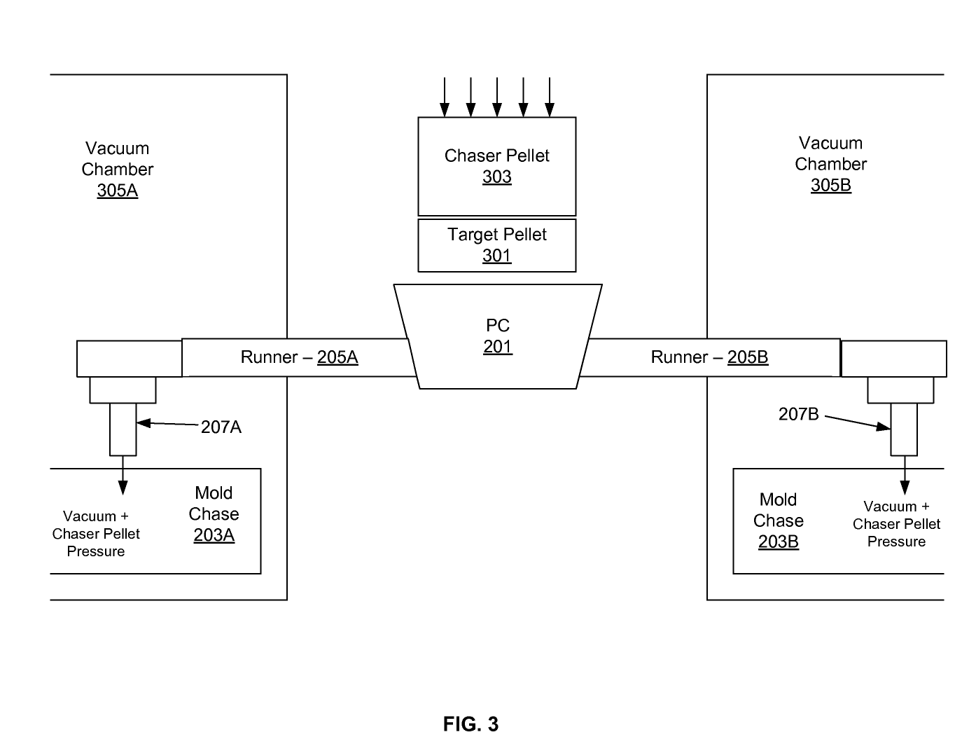

In operation, mold pellets may be placed in the pellet chamber 201 for subsequent heating and melting. The melted mold material may be pushed out of the pellet chamber 201 and into the runners 205A and 205B utilizing mechanical pressure on the top of the pellet in the pellet chamber 201. In addition, a vacuum may be applied at the mold gate ends of the runners 205A and 205B to further provide pressure to move the mold material. This may be accomplished by placing the mold chases 203A and 203B in a vacuum chamber, as described further with respect to FIG. 3.

While two runners 205A and 205B are shown in FIG. 2, the invention is not so limited. Accordingly, any number of runners and mold chases may be utilized as determined by space requirements and pellet chamber capacity, for example.

In an example scenario, two pellets, or alternatively a two part pellet, may be utilized as source material for the pellet chamber 201. For example, a first pellet may comprise a target pellet, comprising low alpha material, and a second pellet may comprise a chaser pellet that is not used to encapsulate die in the mold chases 203A and 203B but is utilized to push the mold material from the target pellet to the mold chases 203A and 203B.

In an example scenario, low alpha may refer to material that emits less than 0.002 (or alternatively 0.001) alpha particle counts per hour per square centimeter. While the target pellet comprises low alpha material, the chaser pellet material may comprise higher alpha material, i.e. lower cost material that would not comply with low alpha material standards for semiconductor devices. The trailing pellet, or chaser pellet, may also comprise materials having conditioning properties, such as melamine. Other factors that may be utilized to determine materials for the chaser and target pellets may be the thermal coefficient of expansion, the modulus, and flowability.

The pellet or pellets placed in the pellet chamber 201 may comprise a separate target pellet and a chaser pellet, or may comprise a single pellet comprising a target portion on the bottom and a chaser portion on top. Furthermore, the chaser pellet may comprise a material of a different density than the material of the target pellet to prevent mixing of the different materials.

FIG. 3 is a drawing illustrating utilization of a chaser pellet to apply mold material to a semiconductor die and packaging substrate, in accordance with an example embodiment of the invention. Referring to FIG. 3, there is shown the pellet chamber 201, the mold chases 203A and 203B, the runners 205A and 205B, the mold gates 207A and 207B, a target pellet 301, a chaser pellet 303, and vacuum chambers 305A and 305B. The apparatus shown in FIG. 3 may share any or all characteristics with the apparatus illustrated in FIG. 2.

The target pellet 301 may comprise a desired mold material for use in generating a mold encapsulation for die placed in the mold chases 203A and 203B. For example, the target pellet 301 may comprise a low alpha epoxy mold compound.

The chaser pellet 303 may comprise a different mold material than the target pellet 301 such that the respective mold materials of the chase pellet and target pellet do not mix when melted. The chase pellet 303 may, for example, be utilized to push the mold material from the target pellet 301 through the runners 205A and 205B. For example, mechanical pressure may be applied against the chaser pellet 303 to push the molten material of the target pellet 301 through the runners 205A and 205B when the pellets melt.

In an example scenario, the target pellet 301 may comprise a low alpha epoxy mold compound, such that the alpha radiation emitted from the target pellet 301 is below industry standard levels required for low alpha materials. For example, the target pellet may emit less than 0.002 (or alternatively 0.001) alpha particle counts per hour per square centimeter.

The chaser pellet 303 may comprise a different material than that of the target pellet 301, such as or example a material that does not conform to low alpha material requirements. Thus, residual mold material left in the pellet chamber 201 and the runners 205A and 205B after a semiconductor package is molded may comprise lower cost materials, as compared to an implementation using only low alpha material which may result in waste of costly materials.

The vacuum chambers 305A and 305B may comprise volumes around the mold chases 203A and 203B that assist in the application of vacuum to the mold chases 203A and 203B, such that the mold material flow may be assisted due to the pressure difference from the pellet chamber 201 to the mold chases 203A and 203B. A vacuum may, for example, be created in the vacuum chambers 305A and 305B utilizing a pumping mechanism. Note that any of a variety of alternative vacuum structures may be utilized to reduce pressure on the mold chases 203A and 203B (e.g., in respective cavities thereof) relative to the pellet chamber 201 such that the pressure differential between the mold chases 203A and 203B and the pellet chamber 201 draws molten mold material from the pellet chamber 201 into respective cavities of the mold chases 203A and 203B via the respective runners 205A and 205B.

In such an example configuration, physical pressure on the chaser pellet 303 and/or the vacuum in the vacuum chambers 305A and 305B may force molten mold material from the target pellet 301 from the pellet chamber 201 through the runners 205A and 205B and the mold gates 207A and 207B to the mold chases 203A and 203B. The chaser pellet 303 may comprise a different density material than the target pellet 301 to avoid intermixing of materials during transferal from the pellet chamber 201 to the mold chases 203A and 203B.

While both mechanical pressure and vacuum pressure are shown in FIG. 3 for transporting molten material from the target pellet 301, it is noted that vacuum pressure is not necessary as mechanical pressure alone may be adequate. Furthermore, vacuum pressure alone may be sufficient to draw the molten target pellet 301 through the runners 205A and 205B.

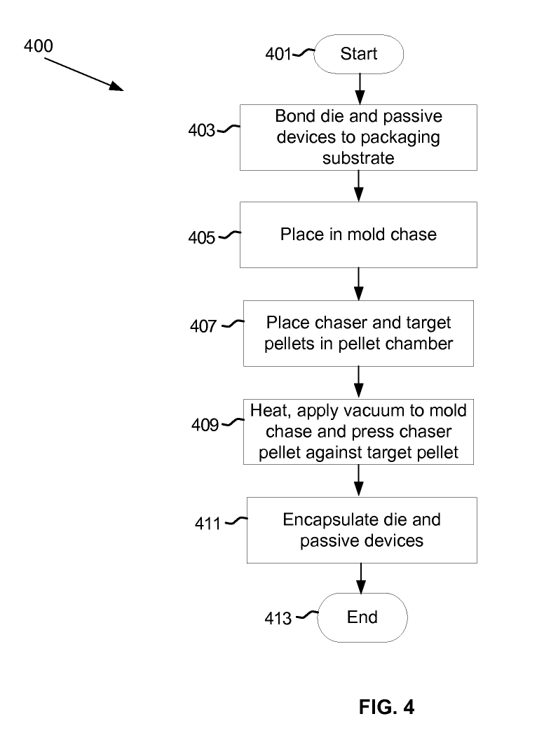

FIG. 4 is a flow diagram illustrating a mold encapsulation process 400 utilizing a chaser pellet, in accordance with an example embodiment of the invention. The steps illustrated in the flow diagram 400 may share any or all characteristics with process and/or structural aspects discussed previously with regard to FIGS. 1-3. Referring to FIG. 4, there is shown an example mold encapsulation process 400 starting with start step 401 followed by step 403 where one or more semiconductor die and/or one or more passive devices may be bonded to a packaging substrate (e.g., any substrate to which a semiconductor die may be bonded). The die may comprise electrical circuitry such as digital signal processors (DSPs), network processors, power management units, audio processors, RF circuitry, wireless baseband system-on-chip (SoC) processors, sensors, and application specific integrated circuits, for example. In addition, passive devices may also be coupled to the packaging substrate.

In step 405, the bonded die/substrate assembly may be placed in a mold chase for encapsulation of the semiconductor die and/or passive devices on the packaging substrate. In step 407 a target pellet may be placed in a pellet chamber followed by a chaser pellet. The target pellet may comprise low alpha epoxy mold compound, such that the alpha radiation emitted from the target pellet is below industry standard levels required for low alpha materials. For example, the target pellet may emit less than 0.002 (or alternatively 0.001) alpha particle counts per hour per square centimeter. The chaser pellet may comprise a different material than that of the target pellet, such as for example a material that does not conform to low alpha material requirements. Note that a pellet comprising a combination of materials, for example in layers or sections, may be utilized (e.g., a first layer of low alpha material and a second layer of non-low alpha material). In other words, the target pellet and the chaser pellet may be combined into a single pellet.

In step 409, the pellet chamber may be heated to melt the mold material in the target pellet, allowing it to flow from the pellet chamber to the mold chase via a runner and mold gate. Physical pressure may be applied against the chaser pellet, and a vacuum may be applied to the mold chase to facilitate the flow of the molten target pellet.

In step 411, the low alpha mold material from the target pellet may flow into the mold chase, encapsulating (e.g., fully encapsulating on all sides, or partially encapsulating on less than all sides) the die and passive devices on the packaging substrate. In addition, the mold material may act as an underfill material, filling the volume between the die and the substrate, providing further isolation as well as physical support. The process then completes with end step 413.

In an embodiment of the invention, a method and system are disclosed for producing a semiconductor package comprising one or more semiconductor die 101 coupled to a packaging substrate 103 where the packaging substrate 103 and the one or more coupled semiconductor die 101 may be placed in a mold chase 203A and 203B. A chaser pellet 303 may be placed on top of a target pellet 301 in a pellet chamber 201 coupled to the mold chase 203A, 203B via a runner 205A, 205B, wherein the target pellet 301 comprises an epoxy mold compound.

Heat may be applied to the pellet chamber 201 to melt the target pellet 301. Pressure may be applied to the chaser pellet 303 to force epoxy mold compound from the molten target pellet 301 through the runner 205A, 205B to the mold chase 203A, 203B. The one or more semiconductor die 101 may be encapsulated with the epoxy mold compound from the molten target pellet 301. One or more passive devices 115A, 115B may be coupled to the packaging substrate 103 and may similarly be encapsulated by the epoxy mold compound (e.g., fully encapsulated on all sides, or partially encapsulated on less than all sides) from the molten target pellet 301.

The mold compound (e.g., epoxy mold compound) of the target pellet 301 may comprise a low alpha material. The low alpha material may emit less than 0.002 (or alternatively 0.001) alpha particle counts per hour per square centimeter. The epoxy mold compound may comprise an underfill material for the one or more semiconductor die 101. A vacuum may be applied at the mold chase 203A, 203B to force the epoxy mold compound from the molten target pellet 301 through the runner 205A, 205B to the mold chase 203A, 203B. The semiconductor package 100 may comprise a flip chip molded ball grid array.

While the invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiments disclosed, but that the present invention will include all embodiments falling within the scope of the appended claims.

What is claimed is:

1. A method for producing a semiconductor package, the semiconductor package comprising a semiconductor die coupled to a packaging substrate, the method comprising:
placing said packaging substrate and said coupled semiconductor die in a mold chase;
placing a chaser pellet on top of a target pellet in a pellet chamber coupled to said mold chase via a runner, wherein said target pellet comprises a mold compound;
applying heat to said pellet chamber to melt said target pellet;
applying pressure to said chaser pellet to force mold compound from the molten target pellet through said runner to said mold chase; and
encapsulating said coupled semiconductor die with the mold compound from the molten target pellet.

2. The method according to claim 1, wherein one or more passive devices are coupled to said packaging substrate and are encapsulated by the mold compound from the molten target pellet.

3. The method according to claim 1, wherein said target pellet comprises a low alpha material.

4. The method according to claim 3, wherein said low alpha material emits less than 0.002 alpha particle counts per hour per square centimeter.

5. The method according to claim 1, comprising underfilling the semiconductor die with the mold compound.

6. The method according to claim 1, comprising applying a vacuum at said mold chase to draw the mold compound from the molten target pellet through said runner to said mold chase.

7. The method according to claim 1, wherein said semiconductor package comprises a flip chip molded ball grid array.

8. A method for producing a semiconductor package, the semiconductor package comprising a semiconductor die coupled to a packaging substrate, the method comprising:
placing said packaging substrate and said coupled semiconductor die in a mold chase;
placing a mold compound pellet in a pellet chamber coupled to said mold chase via a runner, wherein an upper part of said mold compound pellet comprises a chaser pellet section and a lower part of said mold compound pellet comprises a target pellet section;
applying heat to said pellet chamber to melt at least said target pellet section;
applying pressure to said chaser pellet section to force mold compound from the molten target pellet section through said runner to said mold chase; and
encapsulating said one or more semiconductor die with the epoxy mold compound from the molten target pellet section.

9. The method according to claim 8, wherein one or more passive devices are coupled to said packaging substrate and are encapsulated by the mold compound from the molten target pellet section.

10. The method according to claim 8, wherein said target pellet section comprises a low alpha material.

11. The method according to claim 10, wherein said low alpha material emits less than 0.002 alpha particle counts per hour per square centimeter.

12. The method according to claim 8, comprising underfilling the semiconductor die with the mold compound from the molten target pellet section.

13. The method according to claim 8, comprising applying a vacuum at said mold chase to draw the mold compound from the molten target pellet section through said runner to said mold chase.

14. The method according to claim 8, wherein said semiconductor package comprises a flip chip molded ball grid array.

15. A semiconductor package comprising:
a semiconductor die bonded to a packaging substrate;
a mold material encapsulating said semiconductor die, said mold material formed utilizing material from a target pellet that is placed on said packaging substrate utilizing a chaser pellet, wherein said target pellet comprises low alpha material.

16. The package according to claim 15, wherein said mold material underfills said semiconductor die.

17. The package according to claim 15, wherein said low alpha material emits less than 0.002 alpha particle counts per hour per square centimeter.

18. The package according to claim 15, wherein said chaser pellet comprises material that emits more than 0.002 alpha particle counts per hour per square centimeter.

19. The package according to claim 15, wherein one or more passive devices are coupled to said packaging substrate and are encapsulated by said mold material.

20. The package according to claim 15, wherein said semiconductor package comprises a flip chip molded ball grid array.

21. A method for producing a semiconductor package, the method comprising
bonding a semiconductor die to a packaging substrate;
placing said packaging substrate and said coupled semiconductor die in a mold chase;
encapsulating said semiconductor die by placing a mold compound pellet in a pellet chamber coupled via a runner to said mold chase, wherein an upper part of said mold compound pellet comprises a chaser pellet section and a lower part of said mold compound pellet comprises a target pellet section and said target pellet section comprises low alpha material.

22. The method according to claim 21, comprising underfilling the semiconductor die with mold compound from the molten target pellet section.

23. The method according to claim 21, wherein said low alpha material emits less than 0.002 alpha particle counts per hour per square centimeter.

24. The method according to claim 21, comprising coupling one or more passive devices to said packaging substrate before encapsulating with mold compound from the molten target pellet section.

25. The method according to claim 21, wherein said semiconductor package comprises a flip chip molded ball grid array.

26. The method according to claim 21, comprising applying a vacuum at said mold chase to draw mold compound from the target pellet section through a runner to said mold chase.
